(19) United States
(12) Patent Application Publication
(10) Pub. No.: US 2024/0402268 A1
(43) Pub. Date: Dec. 5, 2024

(54) MAGNETIC SENSOR

(71) Applicant: TDK CORPORATION, Tokyo (JP)

(72) Inventor: Takafumi KOBAYASHI, Tokyo (JP)

(73) Assignee: TDK CORPORATION, Tokyo (JP)

(21) Appl. No.: 18/666,979

(22) Filed: May 17, 2024

(30) Foreign Application Priority Data
May 29, 2023 (JP) 2023-088152

(51) Int. Cl. G01R 33/09; H04N 23/50

(52) U.S. Cl. CPC G01R 33/098; H04N 23/50

(57) ABSTRACT

The present disclosure provides a magnetic sensor including: a magnetic field detector that includes a magnetic detection element; a first magnetic shield and a second magnetic shield that are disposed so as to sandwich the magnetic field detector therebetween in a first direction; and a third magnetic shield that is disposed on a side of the magnetic field detector in a second direction that is orthogonal to the first direction.

### CROSS REFERENCE TO RELATED APPLICATION

This application claims the benefit of Japanese Priority Patent Application No. 2023-088152 filed on May 29, 2023, the entire contents of which are incorporated herein by reference.

### FIELD

The present disclosure relates to a magnetic sensor.

### BACKGROUND

In recent years, physical quantity detection devices (position detection devices) for detecting physical quantities (for example, the position or the amount of movement (change amount) or the like of a moving object resulting from rotational movement or linear movement thereof) have been used in various applications. As an example of this physical quantity detection device, there is a known device that includes a magnetic sensor capable of detecting changes in an external magnetic field and a magnetic field generator (for example, a magnet) capable of changing the position thereof relative to the magnetic sensor, and a sensor signal corresponding to changes in the external magnetic field is output from the magnetic sensor.

As an example of a magnetic sensor, there is a known sensor in which a magnetic sensor element that detects a detection-target magnetic field is provided on a substrate, and as such a magnetic sensor element, for example, a magnetoresistive device (a GMR element, a TMR element, or the like) in which resistance changes according to changes in an external magnetic field is used.

The above magnetoresistive element is constituted by a layer structure including at least a free layer, the magnetization direction of which can be changed in response to an external magnetic field, a magnetization pinned layer, the magnetization direction of which is pinned, and a non-magnetic layer interposed between the free layer and the magnetization pinned layer. In a magnetoresistive element having such a structure, the resistance value of the magnetoresistive element is determined by the angle between the magnetization direction of the free layer and the magnetization direction of the magnetization pinned layer. The magnetization direction of the free layer changes in response to the external magnetic field, the angle between the magnetization directions of the free layer and the magnetization pinned layer changes accordingly, and consequently the resistance value of the magnetoresistive element changes. Due to this change in resistance value, a sensor signal corresponding to the change in the external magnetic field is output. A magnetoresistive element provided on the substrate is often configured to be sensitive to the magnetic field in a direction parallel to the surface of the substrate.

On the other hand, in a magnetic sensor, there is a demand for detecting the magnetic field in a direction orthogonal to the surface of the substrate using the magnetoresistive element provided on the substrate. For example, Patent Publication JP-A 2022-123321 discloses a magnetic sensor including: a magnetic shield that shields an external magnetic field extending along a plane direction of a substrate; a magnetic field detector; a magnetic field convertor that converts the magnetic field component oriented in a direction orthogonal to a surface of the substrate into the magnetic field component oriented in the plane direction of the substrate and applies the converted magnetic field component to the magnetic field detector.

Note that U.S. Patent Application Publication No. 2023/0014296 discloses a magnetic shield for a magnetic device such as vertically oriented magnetoresistive random access memories (MRAM), used to minimize interference from the external magnetic fields in the vertical and plane directions. However, the technology disclosed in U.S. Patent Application Publication No. 2023/0014296 is a technology for shielding the MRAM from interference of external magnetic fields, and is fundamentally different from the magnetic shielding technology used in a magnetic sensor that detects external magnetic fields.

### SUMMARY

In recent years, camera modules for optical image stabilization (OIS) and the like have required stronger driving power due to the increase in lens size. As a result, the magnetic fields generated by the drive magnets of the modules are becoming stronger. In such an environment, the strength of the magnetic field to be detected is also stronger, and the magnetic sensor used is required to have a wider magnetic field detection range.

However, when the magnetic field orthogonal to the substrate surface is strong, a problem arises in which the magnetic field detection range of the magnetic sensor (hereinafter also referred to as a “Z-axis magnetic sensor”) that detects the magnetic field orthogonal to the substrate surface decreases. This is because, for example, when a strong magnetic field orthogonal to the surface of the substrate (hereinafter also referred to as a “Z magnetic field”) is applied to the Z-axis magnetic sensor, the free layer magnetization of the TMR element, for example, begins to rotate in the Z direction, resulting in a decrease in output. Such rotation of the free layer magnetization becomes an obstacle to expanding the detection range of the Z magnetic field.

In particular, when the magnetic shields that shield external magnetic fields along the plane direction of the substrate are placed above and below the TMR element, the magnetic flux oriented in the Z direction is converged by the magnetic shields, and a stronger Z magnetic field is applied to the TMR element. As a result, there is a problem in that the magnetic field detection range tends to further decrease.

A magnetic sensor according to one aspect of the present disclosure includes: a magnetic field detector that includes a magnetic detection element; a first magnetic shield and a second magnetic shield that are disposed so as to sandwich the magnetic field detector therebetween in a first direction; and a third magnetic shield that is disposed on a side of the magnetic field detector in a second direction that is orthogonal to the first direction.

A magnetic sensor according to one aspect of the present disclosure includes: a magnetic field detector that includes a magnetic detection element; a first magnetic shield and a second magnetic shield that are disposed so as to sandwich the magnetic field detector therebetween in a first direction; and a third magnetic shield configured to converge a magnetic flux oriented in the first direction and reduce a magnetic flux applied to the magnetic field detector.

In the magnetic sensor according to one aspect of the present disclosure, part or all of the third magnetic shield may be disposed between the first magnetic shield and the second magnetic shield. In addition, the third magnetic shield may have a flat shape in the second direction orthogonal to the first direction.

In the magnetic sensor according to one aspect of the present disclosure, the magnetic field detector may be provided as a plurality of magnetic field detectors, and the third magnetic shield may be formed for each of the plurality of magnetic field detectors.

The magnetic sensor according to one aspect of the present disclosure may further include: a magnetic field convertor configured to convert a magnetic field component oriented in the first direction into a magnetic field component oriented in a second direction that is orthogonal to the first direction, and apply the converted magnetic field component to the magnetic field detector.

In the magnetic sensor according to one aspect of the present disclosure, a position of the magnetic field convertor may overlap a position of the third magnetic shield as viewed from a direction orthogonal to the first direction. In addition, a position of the magnetic field detector may overlap a position of the third magnetic shield and the position of the magnetic field detector may overlap a center position of the third magnetic shield in the first direction, as viewed from a direction orthogonal to the first direction.

In the magnetic sensor according to one aspect of the present disclosure, the magnetic detection element may be disposed obliquely with respect to the second direction orthogonal to the first direction.

In the magnetic sensor according to one aspect of the present disclosure, the magnetic field detector may be provided as a plurality of magnetic field detectors, and the plurality of magnetic field detectors are connected in a form of a bridge circuit.

In the magnetic sensor according to one aspect of the present disclosure, the third magnetic shield may be in contact with one or both of the first magnetic shield and the second magnetic shield, or separated from one or both of the first magnetic shield and the second magnetic shield.

In the magnetic sensor according to one aspect of the present disclosure, the third magnetic shield may surround the magnetic field detector in the second direction orthogonal to the first direction.

A camera module according to one aspect of the present disclosure includes an autofocus mechanism and/or an optical image stabilization mechanism including the above-described magnetic sensor.

### BRIEF DESCRIPTION OF DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1A is a perspective view showing a schematic configuration of a magnetic sensor according to one example embodiment of the present disclosure;

FIG. 1B is a plan view of the magnetic sensor in FIG. 1A;

FIG. 2A is a schematic diagram showing convergence of a magnetic flux oriented in a Z direction by a first magnetic shield and a second magnetic shield;

FIG. 2B is a schematic diagram showing an aspect in which a third magnetic shield forms a magnetic path and reduces a first magnetic field component applied to a magnetic field detector;

FIG. 2C is a diagram showing a Z magnetic field simulation when a Z direction magnetic field of 500 mT is applied;

FIG. 3A is a perspective view showing a schematic configuration of the magnetic sensor according to one example embodiment;

FIG. 3B is a side view showing a schematic configuration of the magnetic sensor according to one example embodiment;

FIG. 3C is a side view showing a schematic configuration of the magnetic sensor according to one example embodiment;

FIG. 3D is a side view showing a schematic configuration of the magnetic sensor according to one example embodiment;

FIG. 3E is a side view showing a schematic configuration of the magnetic sensor according to one example embodiment;

FIG. 3F is a side view showing a schematic configuration of the magnetic sensor according to one example embodiment;

FIG. 3G is a side view showing a schematic configuration of the magnetic sensor according to one example embodiment;

FIG. 3H is a side view showing a schematic configuration of the magnetic sensor according to one example embodiment;

FIG. 3I is a partially enlarged view of a range S in FIG. 3H;

FIG. 3J is a schematic diagram showing a formula for calculating a resistance R of a magnetoresistive element;

FIG. 3K is a schematic diagram showing a formula for calculating the resistance R of the magnetoresistive element;

FIG. 4A is a plan view showing a schematic configuration of the magnetic sensor according to one example embodiment;

FIG. 4B is a plan view showing a schematic configuration of the magnetic sensor according to one example embodiment;

FIG. 4C is a plan view showing a schematic configuration of the magnetic sensor according to one example embodiment;

FIG. 4D is a plan view showing a schematic configuration of the magnetic sensor according to one example embodiment;

FIG. 5 is a plan view showing an example of a magnetic sensor configured as a magnetic compass;

FIG. 6A is a perspective view showing an example of a magnetic sensor used as part of an autofocus mechanism and an optical image stabilization mechanism of a camera module; and

FIG. 6B is a cross-sectional view showing an internal structure of the camera module shown in FIG. 6A.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

The present disclosure has been made in view of the above circumstances, and an object thereof is to provide a magnetic sensor, the magnetic field detection range of which is less likely to decrease even when a strong Z magnetic field is applied.

Hereinafter, one example embodiment of the present disclosure (hereinafter also referred to as the “present embodiment”) will be described with reference to the drawings. Note that, for the sake of ease of illustration and understanding, the scale, aspect ratio, etc. in the drawings attached to the present specification may be appropriately changed or exaggerated from those of the actual item.

An “X direction”, an “Y direction”, a “Z direction”, and a “XY plane direction” are defined as required. Here, the “XY plane direction” is the plane direction of a substrate on which a magnetic sensor is formed, and is also the plane direction of a first magnetic shield or a second magnetic shield in one example embodiment of the present disclosure. The “X direction” and the “Y direction” are directions orthogonal to each other within the XY plane. Furthermore, the “Z direction” is the thickness direction of the substrate on which the magnetic sensor is formed, and is also a direction orthogonal to the XY plane direction.

Note that the “first direction” in the present disclosure may be the Z direction, and the “second direction” may be any direction in the XY plane.

Terms and/or numerical values denoting shapes and/or geometrical conditions do not need to be restricted to strict meanings, and may be interpreted to include a range to the extent that similar functions may be expected. For example, the term(s) “parallel” and/or “orthogonal”, etc. fall under the above terms. In addition, the term(s) “length value” and/or “angle value”, etc. fall under the above numerical values.

When a component is referred to as being “on”, “under”, “on the upper side of”, “on the lower side of”, “above”, or “below” another component, an aspect in which the component is in direct contact with the other component and an aspect in which yet another component is interposed between the component and the other component may be included. In other words, the aspect in which another component is interposed between the component and the other component may be expressed as an aspect in which the component is in indirect contact with the other component. In addition, the expression “on”, “on the upper side of”, or “above” is interchangeable with the expression “under”, “on the lower side of”, or “below”. In other words, the top and bottom may be reversed. The same applies to the left and right.

When assigning the same or similar symbols to the same portions and/or portions having similar functions, redundant descriptions may be omitted. The dimensional ratios in the drawings may differ from the actual ratios. Part of the configuration according to one example embodiment may be omitted from the drawings.

One or more aspects of one example embodiment and one or more aspects of a modification may be combined to the extent that no contradiction occurs. One or more aspects of one example embodiment may be combined to the extent that no contradiction occurs. One or more aspects of the modification may be combined to the extent that no contradiction occurs.

When a plurality of steps are disclosed for a method such as a manufacturing method, other steps not disclosed may be carried out between the disclosed steps. The order of the steps is not limited as long as no contradiction occurs.

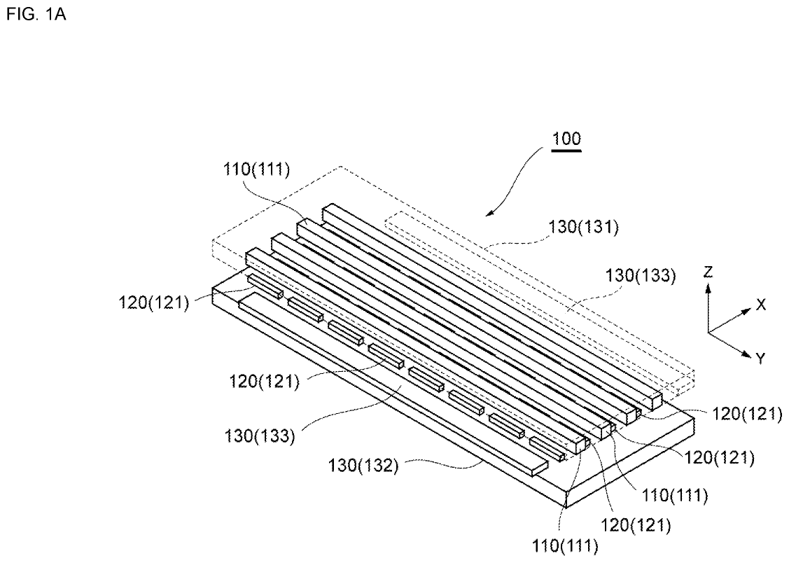

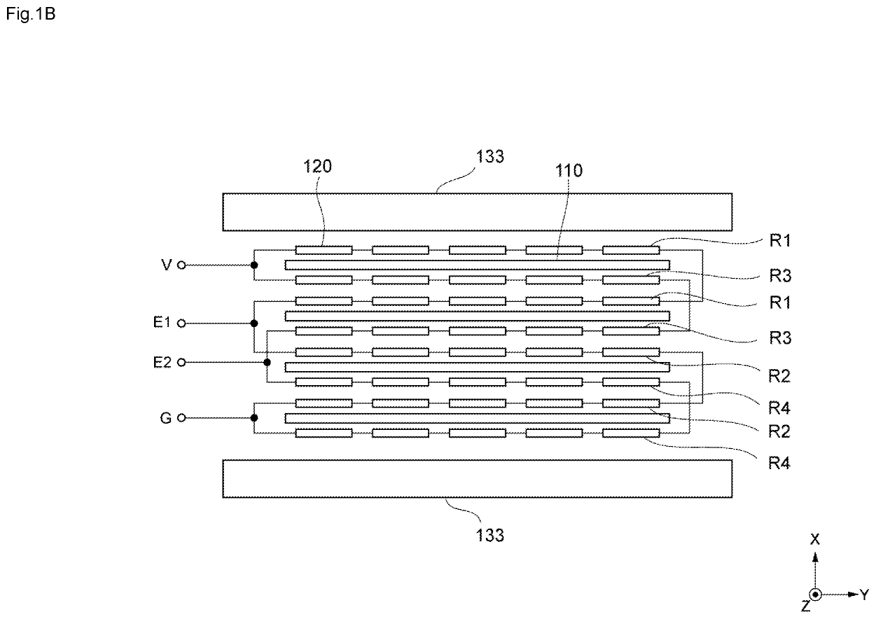

FIG. 1A is a perspective view showing a schematic configuration of a magnetic sensor 100 according to one example embodiment of the present disclosure. FIG. 1B is a plan view showing the magnetic sensor 100 in FIG. 1A as viewed in a direction from a first magnetic shield 131. In FIG. 1B, the first magnetic shield 131 is not expressed.

As shown in FIGS. 1A and 1B, the magnetic sensor 100 includes a magnetic field converter 110, a magnetic field detector 120, and magnetic shields 130. As shown in FIG. 1A, the magnetic shields 130 include the first magnetic shield 131 and a second magnetic shield 132 located above and below the magnetic field detector 120 in the Z direction, and third magnetic shields 133 located on the left and right sides of the magnetic field detector 120 in the X direction. The following describes each component in detail.

The magnetic field converter 110 converts the magnetic field component oriented in the Z direction (hereinafter also referred to as a “first magnetic field component H1”) into a magnetic field component oriented in a direction in the XY plane (hereinafter also referred to as a “second magnetic field component H2”), and applies the second magnetic field component H2 to the magnetic field detector 120. As a result, the magnetic field detector 120 can output a signal corresponding to changes in the first magnetic field component H1.

The positional relationship between the magnetic field converter 110 and the magnetic field detector 120 is not particularly limited, but the magnetic field detector 120 may be provided at a position where the magnetic field output from the magnetic field converter 110 can be applied. One magnetic field convertor 110 may be provided for one magnetic field detector 120, or one magnetic field convertor 110 may be provided for a plurality of magnetic field detectors 120.

The magnetic field converter 110 may be constituted by one or more yokes 111 made of a soft magnetic material. Although FIGS. 1A and 1B show the yokes 111 as rectangular parallelepipeds extending in the Y direction, there is no restriction on the shapes of the yokes 111 as long as the yokes 111 can apply the second magnetic field component H2 to the magnetic field detector 120.

Although there is no restriction on the material of the yokes 111, examples of which include soft magnetic materials such as permalloy (NiFe).

The magnetic field detector 120 outputs a signal corresponding to changes in the second magnetic field component H2. Here, the second magnetic field component H2 is the first magnetic field component H1 converted by the magnetic field converter 110. In addition, the magnetic field detector 120 is shielded by the first magnetic shield 131 and the second magnetic shield 132, which will be described later, from the external magnetic fields in the XY plane direction. Therefore, the signal output from the magnetic field detector 120 is a signal corresponding to changes in the first magnetic field component H1.

The magnetic field detector 120 may include one or more magnetic detection elements 121. Each magnetic detection element need only be an element that has the function of detecting a magnetic field, examples of which include a tunnel magnetoresistive element (TMR element), a giant magnetoresistive element (GMR element), an anisotropic magnetoresistive element (AMR element), a Hall element, and other types of magnetic detection elements. Among these examples, the TMR element is particularly suitable for the magnetic detection elements 121 because it has a small junction area compared to other types of MR elements, allowing the sensor chip to be made smaller, and has a large MR ratio, allowing the output of the sensor chip to be increased.

As shown in FIGS. 1A and 1B, the number and the arrangement of the magnetic detection elements 121 in the magnetic field detector 120 are illustrative and are not limited thereto. For example, the magnetic field detector 120 may include one magnetic detection element 121, or an element array in which a plurality of magnetic detection elements 121 arranged in a matrix are electrically connected in series. FIGS. 1A and 1B show an aspect in which the magnetic field detector 120 included an element array in which a plurality of magnetic detection elements 121 arranged in a matrix are electrically connected in series.

The magnetic sensor 100 may include a plurality of magnetic field detectors 120. For example, the magnetic sensor 100 may include four magnetic field detectors 120, and the four magnetic field detectors 120 may form a bridge circuit such as a Wheatstone bridge circuit in which the magnetic field detectors 120 are bridged. In addition, the magnetic sensor 100 may include four magnetic field detector groups each group consisting of a plurality of magnetic field detectors 120, and the four magnetic field detector groups form a Wheatstone bridge circuit in which the four magnetic field detector groups are bridged. Note that in each magnetic field detection unit group, the plurality of magnetic field detectors 120 may be connected in series or in parallel.

For example, FIG. 1B shows an aspect in which the magnetic sensor 100 includes four magnetic detector groups, namely a first magnetic field detector group R1, a second magnetic field detector group R2, a third magnetic field detector group R3, and a fourth magnetic field detector group R4. The Wheatstone bridge circuit shown in FIG. 1B includes a power port V, a ground port G, a first output port E1, a second output port E2, a first magnetic field detector group R1 provided between the power port V and the first output port E1, a second magnetic field detector group R2 provided between the first output port E1 and the ground port G, a third magnetic field detector group R3 provided between the power port V and the second output port E2, and a fourth magnetic field detector group R4 provided between the second output port E2 and the ground port G. A constant current source is connected to the power port V to apply a power voltage (constant current) of a predetermined magnitude, and the ground port G is connected to the ground. The constant current supplied to the power port V is controlled by a driver IC (not shown) so as to be a predetermined current value. Note that a constant voltage may be applied to the power port V.

In the bridge configuration shown in FIG. 1B, the direction of the magnetic field bent by the yokes and the direction of the magnetization pinned layer may be combined as follows in order to obtain an output. For example, when a magnetic field is applied in the Z direction from the second magnetic shield 132 side to the first magnetic shield 131 side, the resistance of each magnetic field detector group changes as follows. In the first magnetic field detector group R1, the direction of the free layer magnetization changes to a direction antiparallel to the magnetization pinned layer magnetization, and the resistance increases. In the second magnetic field detector group R2, the direction of the free layer magnetization changes to a direction parallel to the magnetization pinned layer magnetization, and the resistance decreases. In the third magnetic field detector group R3, the direction of the free layer magnetization changes to a direction parallel to the magnetization pinned layer magnetization, and the resistance decreases. In the fourth magnetic field detector group R4, the direction of the free layer magnetization changes to a direction antiparallel to the magnetization pinned layer magnetization, and the resistance increases. At this time, the magnitude of the relative angle between the free layer magnetization and the magnetization pinned layer magnetization changes depending on the strength of the applied Z magnetic field. As a result, the magnitude of Z magnetic field can be obtained in the form of a differential potential (E1-E2) in the Wheatstone bridge circuit.

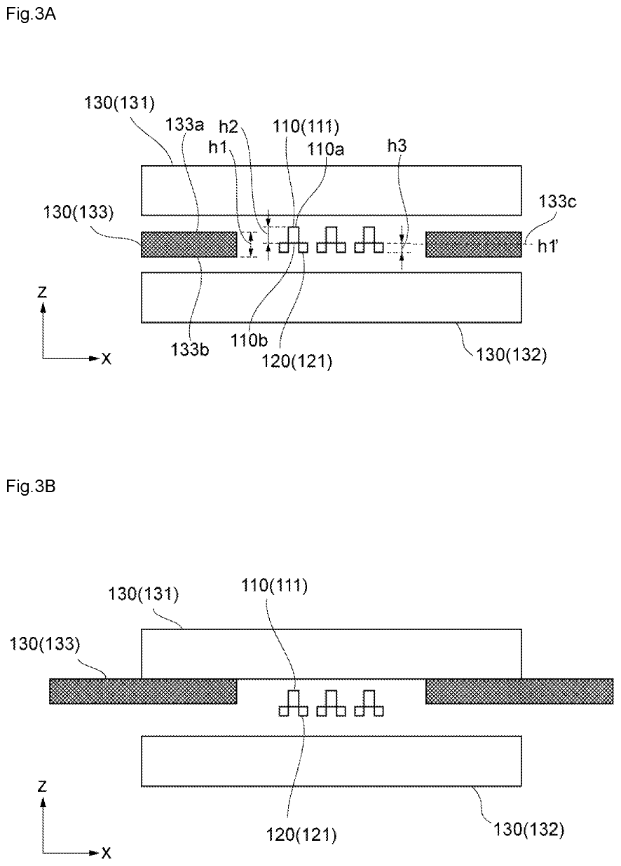

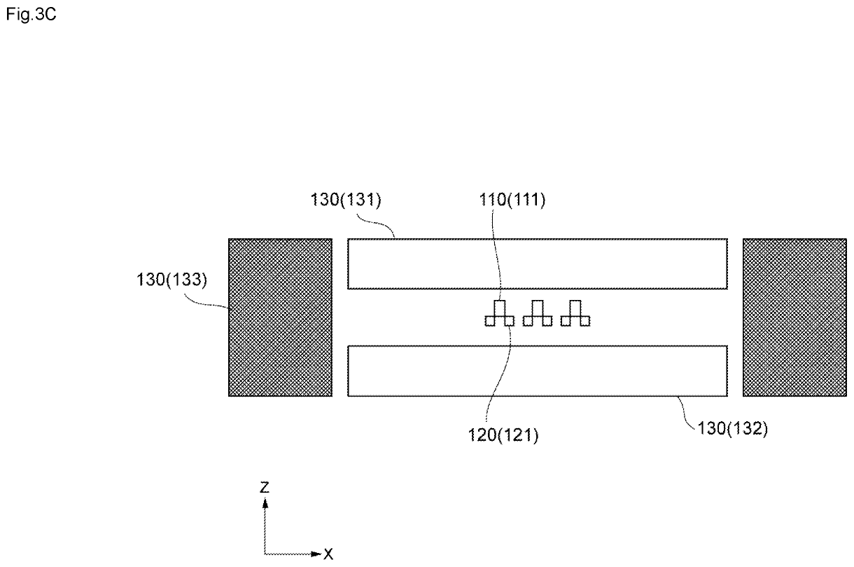

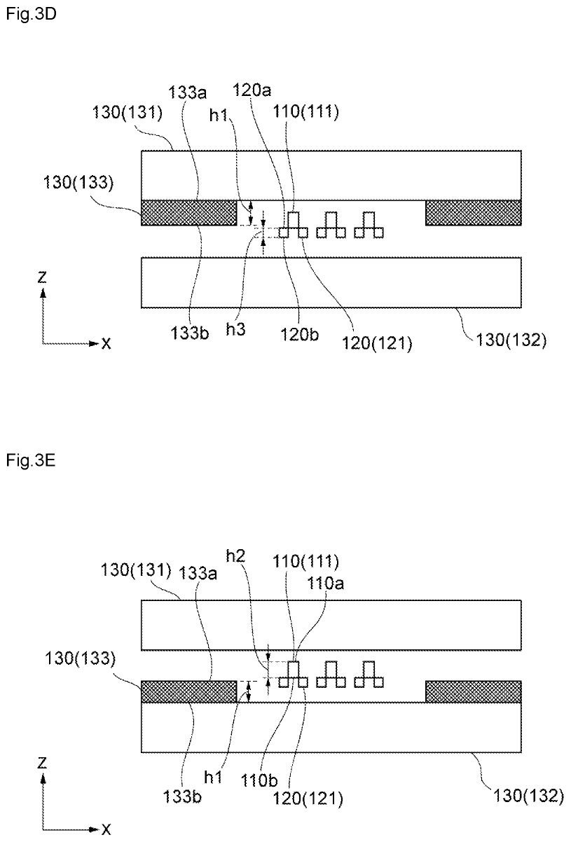

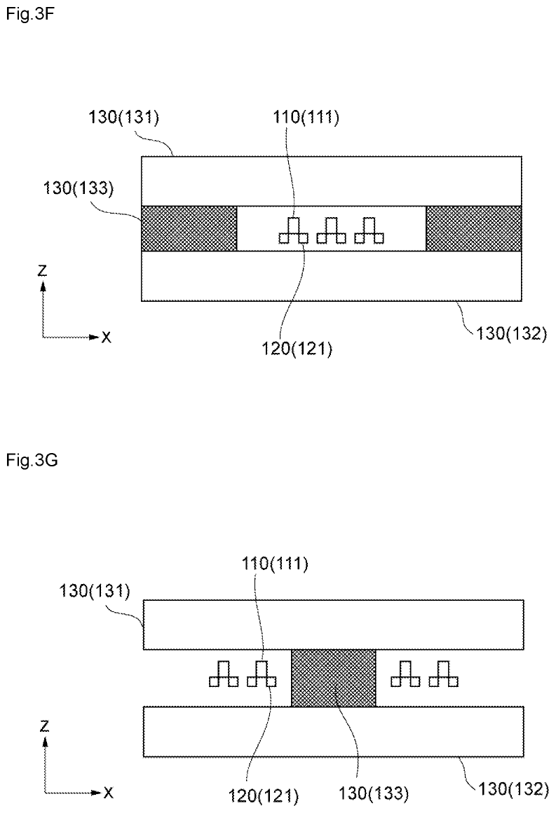

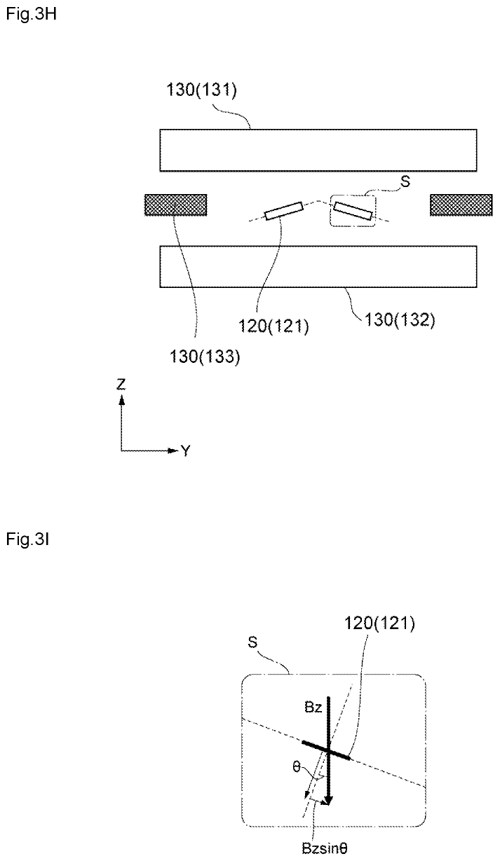

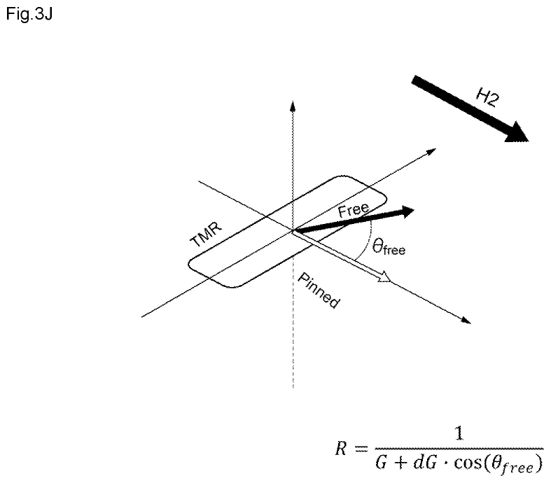

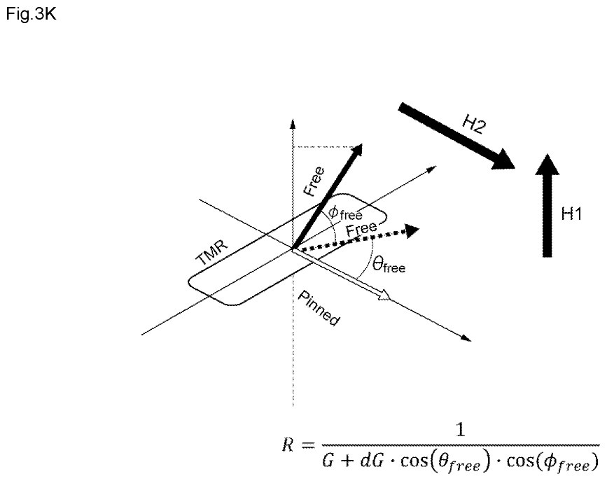

The magnetic field detector 120 may be disposed parallel to the XY plane direction as shown in FIGS. 1A and 1B, or obliquely with respect to the XY plane direction as shown in FIG. 3H. When the magnetic field detector 120 is disposed parallel to the XY plane direction, manufacturing efficiency tends to be improved compared to when the magnetic field detector 120 is disposed at an angle to the XY plane direction. When the magnetic field detector 120 is disposed obliquely with respect to the XY plane direction, the magnetic field converter 110 does not necessarily an essential component.

More specifically, as shown in FIG. 3I, in the partially enlarged view of a range S in FIG. 3H, the magnetic field detector 120 disposed at an angle θ detects a magnetic field component Bz oriented in the Z direction as Bzsinθ. Therefore, for the magnetic field detector 120 disposed at the angle θ, there is no need to use the magnetic field converter 110 to convert the magnetic field component oriented in the Z direction into a magnetic field component oriented in a direction in the XY plane.

Furthermore, by employing a configuration in which the magnetic field converter 110 is not provided, a relatively uniform magnetic field can be applied compared to the case where the magnetic field converter 110 is provided. For example, the magnetic field component oriented in the Z direction is converted by the yokes 111 into a magnetic field component oriented in a direction in the XY plane.

At this time, the intensity of the magnetic field component oriented in any direction in the XY plane and applied to the magnetic field detector 120, changes depending on the distance from the yokes 111 in the XY plane direction. Therefore, a non-uniform in-plane magnetic field is applied to the magnetic field detector 120 in the XY plane direction. More specifically, for example, near an end portion of a yoke 111, the in-plane magnetic field component is large, whereas the in-plane magnetic field component decreases as the distance from the end portion of the yoke 111 increases outward. Therefore, when comparing an end portion of the magnetic field detector 120 near an end portion of the yoke 111 and an end portion of the magnetic field detector 120 far from an end portion of the yoke 111, the former receives a large in-plane magnetic field while the latter receives a relatively weak in-plane magnetic field. In contrast, by disposing the magnetic field detector 120 at an angle with respect to the XY plane direction and not providing the magnetic field converter 110, the issue of the non-uniformity of the in-plane magnetic field depending on the distance from the yoke 111 can be avoided, and the influence of the linearity of the change in resistance of the magnetic field detector 120 caused by the non-uniformity of the in-plane magnetic field can be avoided.

The first magnetic shield 131 and the second magnetic shield 132 are disposed so as to sandwich the magnetic field detector 120 therebetween as viewed in the Z direction. That is to say, the first magnetic shield 131 and the second magnetic shield 132 overlap the magnetic field detector 120 in the Z direction. As a result, the magnetic flux oriented in the XY plane direction is converged by the first magnetic shield 131 and the second magnetic shield 132, and the magnetic field detector 120 is shielded from the external magnetic field in the XY plane direction. Therefore, a magnetic field in the Z direction is effectively applied to the magnetic field detector 120.

Note that the first magnetic shield 131 and the second magnetic shield 132 may overlap a portion of the magnetic field detector 120 or the entire magnetic field detector 120 in the Z direction as long as the effect of the magnetic sensor 100 according to one example embodiment can be achieved. In addition, the first magnetic shield 131 may overlap a portion of the second magnetic shield 132 or the entire second magnetic shield 132 in the Z direction.

The shapes of the first magnetic shield 131 and the second magnetic shield 132 in the XY plane direction are not particularly limited, and examples of which include a square shape, a rectangular shape, the four corner angles of which are 89 to 91 degrees, a rounded rectangular shape with four rounded corners, a rectangular shape with four chamfered corners (octagonal shapes), oval shapes including an ellipse shape, a rectangular shape with two opposite short sides arcuate, a trapezoid shape, a parallelogram shape, a rhombus shape, and so on. In addition, in the case where the first magnetic shield 131 and the second magnetic shield 132 have a rectangular shape, at least one pair of opposite two sides of the two pairs of opposite two sides may be parallel, or the two pairs of opposite two sides may be non-parallel. The shapes of the first magnetic shield 131 and the second magnetic shield 132 in the XY plane direction may be the same or different.

In addition, the first magnetic shield 131 and the second magnetic shield 132 may be constituted by one magnetic shield as shown in FIGS. 1A and 1B, or constituted by a plurality of magnetic shields arranged side by side in the XY plane direction.

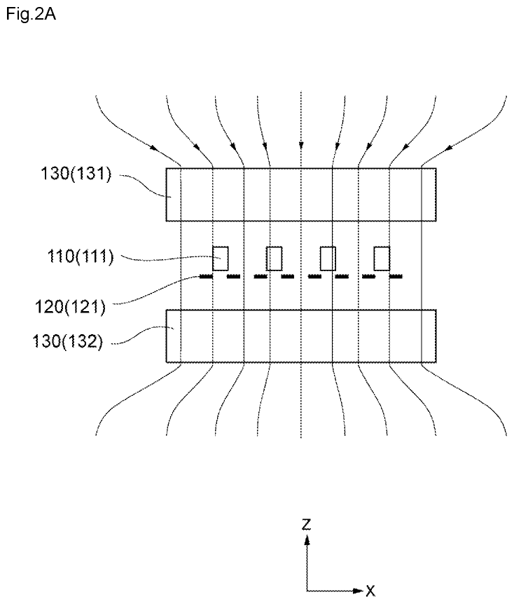

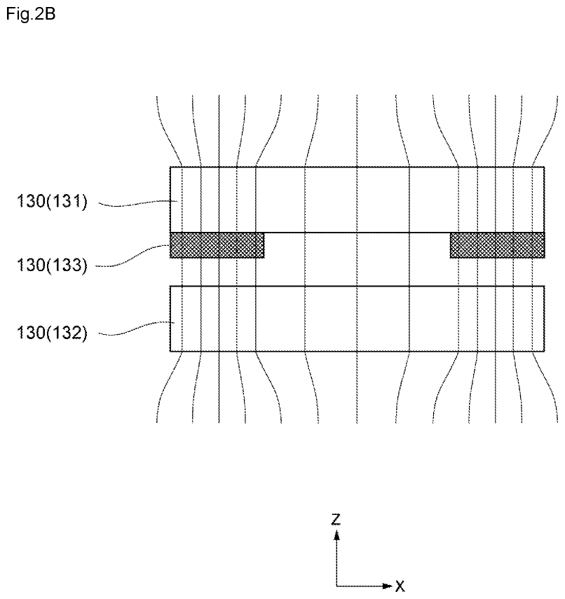

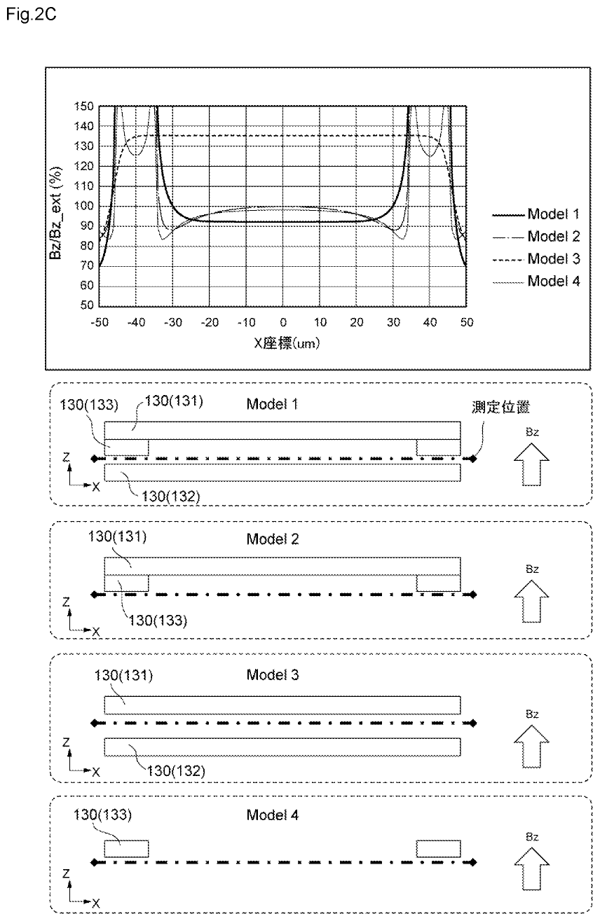

As described above, the first magnetic shield 131 and the second magnetic shield 132 shield the magnetic field detector 120 from the magnetic field in the XY plane direction, while the first magnetic shield 131 and the second magnetic shield 132 converge the magnetic flux oriented in the Z direction. Therefore, as shown in FIG. 2A, a stronger magnetic field in the Z direction is applied to the magnetic field detector 120 located between the first magnetic shield 131 and the second magnetic shield 132.

The mechanism by which the magnetic field detection range of the TMR with respect to the magnetic field in the Z-direction decreases as the first magnetic field component H1 increases as described above will be more specifically described with reference to FIGS. 3J and 3K. Generally, the resistance R of a TMR can be expressed using the difference between a magnetization angle θfree of the free layer and a magnetization angle θpin of the magnetization pinned layer, a conductance G of the TMR, and an amplitude dG of the conductance change. For simplicity, FIG. 3J shows a case where the magnetization angle θpin is 0. In one example embodiment, the magnetic field converter 110 converts a portion of the first magnetic field component H1 in the Z direction into the second magnetic field component H2 in a direction in the XY plane, which is applied to the magnetic field detector 120. When only the second magnetic field component H2 is applied, the magnetization of the free layer rotates in the plane and the magnetization angle θfree changes. The formula for calculating the resistance R at this time is shown in FIG. 3J.

On the other hand, as the magnetic field in the Z direction becomes stronger, i.e., as the first magnetic field component H1 increases, the magnetization of the free layer is rotated in the plane by the second magnetic field component H2, as shown in FIG. 3K, and at the same time the magnetization is rotated by the first magnetic field component H1 with respect to the XY plane by a magnetic field angle ϕfree. As a result, as shown in FIG. 3K, when the first magnetic field component H1 is small, i.e., when ϕfree is close to zero, Cos (ϕfree) is approximately 1 and hardly contributes to the changes in the resistance R. However, as the first magnetic field component H1 increases, the magnetic field angle ϕfree approaches 90 degrees, and as a result, Cos (ϕfree) approaches zero. This reduces the change range of the resistance R, resulting in a reduction of the magnetic field detection range of the magnetic field in the Z direction.

Therefore, in the magnetic sensor 100 according to one example embodiment of the present disclosure, the third magnetic shields 133 are used, as shown in FIG. 2B. With this configuration, the third magnetic shields 133 form a magnetic path and reduce the first magnetic field component H1 applied to the magnetic field detector 120. As a result, even when the magnetic field in the Z direction is strong, it is possible to suppress the output drop caused by the rotation of the magnetization of the free layer in a direction orthogonal to the plane, and improve the magnetic field detection range. Note that in FIG. 2B, the magnetic field converter 110 and the magnetic field detector 120 are omitted.

Next, the third magnetic shields 133 will be described in detail. The third magnetic shields 133 are located on the sides of the magnetic field detector 120 in the XY plane direction. That is to say, the third magnetic shields 133 do not overlap the magnetic field detector 120 in the Z direction. These third magnetic shields 133 converge the magnetic flux oriented in the Z direction between the first magnetic shield 131 and the second magnetic shield 132, and form a magnetic path extending in the Z direction. Therefore, a portion of the first magnetic field component H1 applied to the magnetic field detector 120 is converged by the third magnetic shields 133, and the magnetic field strength of the first magnetic field component H1 applied to the magnetic field detector 120 is reduced. As a result, a decrease in the magnetic field detection range is suppressed, and a magnetic sensor 100 with a wide magnetic field detection range in the Z direction can be realized.

FIG. 2C shows a Z magnetic field simulation when a Z direction magnetic field is applied. The vertical axis in FIG. 2C indicates the ratio of a Z-direction magnetic field Bz at a measurement position to an external Z magnetic field Bz_ext. As shown in FIG. 2C, in Model 1 in which the combination of the first magnetic shield 131, the second magnetic shield 132, and the third magnetic shields 133 is used, the magnetic path formation in the Z direction is stabilized and an excellent effect of suppressing the decrease in the magnetic field detection range in the Z direction can be realized compared to Models 2 to 4 in which the first magnetic shield 131, the second magnetic shield 132, or the third magnetic shields 133 are not used.

Furthermore, as shown in FIG. 2C, in Model 1 in which the combination of the first magnetic shield 131, the second magnetic shield 132, and the third magnetic shields 133 is used, a more uniform magnetic field strength in the Z direction can be obtained at any position in the XY plane direction compared to, for example, Models 2 and 4 or the like in which one or both of the first magnetic shield 131 and the second magnetic shield 132 are not present. Therefore, variations in sensitivity due to differences in the position in the XY plane direction where the magnetic field detector 120 is disposed can be reduced. As a result, even if the mounting positions of the magnetic detection elements 121 are shifted in the XY plane direction during the manufacturing process, sensitivity changes due to the shift can be suppressed. In addition, as shown in FIG. 1B, when a plurality of magnetic detection elements 121 are arranged widely, sensitivity changes due to differences in the positions at which the magnetic detection elements 121 are arranged can also be suppressed.

The first magnetic shield 131, the second magnetic shield 132, and the third magnetic shields 133 may be integrated together, or magnetically coupled together instead of being integrated.

The constituent materials of the first magnetic shield 131, the second magnetic shield 132, and the third magnetic shields 133 are not particularly limited, examples of which include soft magnetic materials such as permalloy (NiFe).

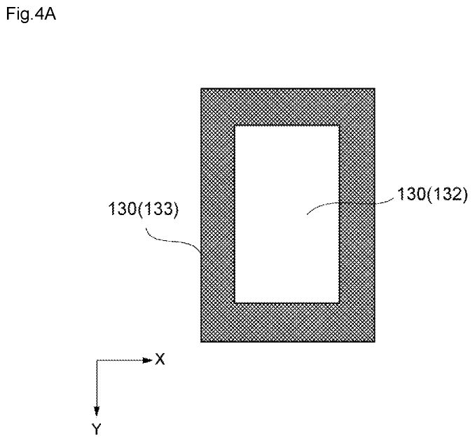

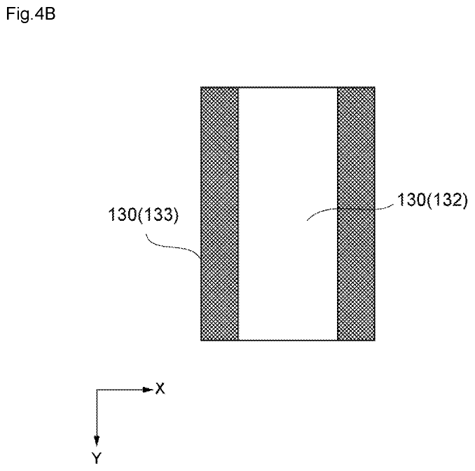

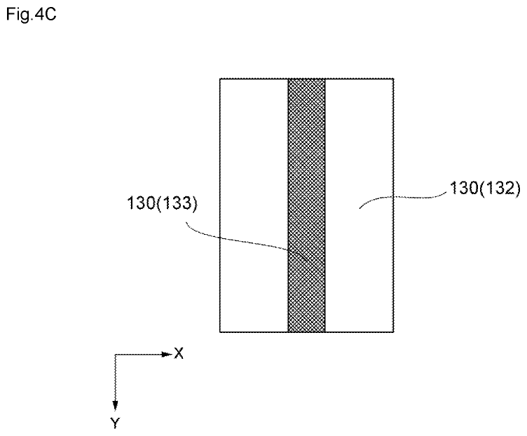

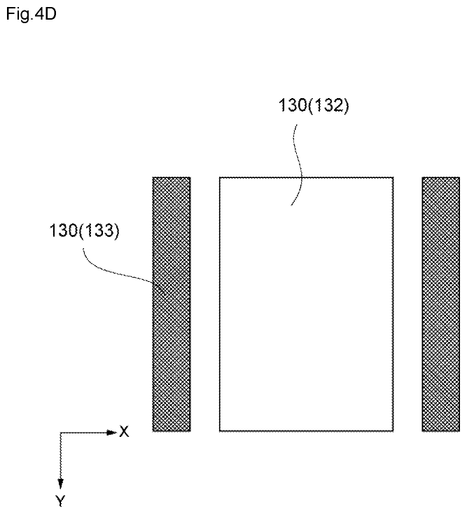

Next, aspects of the third magnetic shields 133 will be further described. FIGS. 3A to 3H show aspects of the third magnetic shields 133 in the Z direction. FIGS. 3A to 3H are side views each showing a schematic configuration of the magnetic sensor 100. FIGS. 4A to 4D show aspects of the third magnetic shields 133 in a cross section parallel to the XY plane direction. FIGS. 4A to 4D are plan views of the magnetic sensor 100 as viewed from the first magnetic shield 131 side. Note that the first magnetic shield 131 is not shown in FIGS. 4A to 4D.

As shown in FIG. 3A, the entirety of each third magnetic shield 133 may be disposed between the first magnetic shield 131 and the second magnetic shield 132. In addition, as shown in FIG. 3B, a portion of each third magnetic shield 133 may be disposed between the first magnetic shield 131 and the second magnetic shield 132. In other words, a portion of each third magnetic shield 133 need not be disposed between the first magnetic shield 131 and the second magnetic shield 132.

As shown in FIG. 3C, the third magnetic shields 133 need not be disposed between the first magnetic shield 131 and the second magnetic shield 132 as long as the effect of the magnetic sensor 100 according to one example embodiment can be achieved. In FIG. 3C, the third magnetic shields 133 are separated from the first magnetic shield 131 and the second magnetic shield 132 in the X direction, but the third magnetic shields 133 may be in contact with the first magnetic shield 131 and the second magnetic shield 132.

Among FIGS. 3A to 3C, as shown in FIG. 3C, when the third magnetic shields 133 are not entirely disposed between the first magnetic shield 131 and the second magnetic shield 132, the third magnetic shields 133 act like yokes in the XY in-plane magnetic field, and are likely to promote the saturation of the first magnetic shield 131 and the second magnetic shield 132 with respect to the XY magnetic field. On the other hand, as shown in FIG. 3A, when the third magnetic shields 133 are entirely disposed between the first magnetic shield 131 and the second magnetic shield 132, the third magnetic shields 133 are less likely to promote the saturation of the first magnetic shield 131 and the second magnetic shield 132 with respect to the XY magnetic field. In addition, the third magnetic shields 133 are less likely to be saturated with respect to the XY magnetic field.

As shown in FIG. 3D, the third magnetic shields 133 may be disposed between the first magnetic shield 131 and the second magnetic shield 132 and in contact with the first magnetic shield 131. In addition, as shown in FIG. 3E, the third magnetic shields 133 may be disposed between the first magnetic shield 131 and the second magnetic shield 132 and in contact with the second magnetic shield 132. Furthermore, as shown in FIG. 3F, the third magnetic shields 133 may be disposed between the first magnetic shield 131 and the second magnetic shield 132 and in contact with both the first magnetic shield 131 and the second magnetic shield 132.

Alternatively, as shown in FIG. 3A, the third magnetic shields 133 may be disposed between the first magnetic shield 131 and the second magnetic shield 132 and separated from both the first magnetic shield 131 and the second magnetic shield 132.

As shown in FIG. 3A, the third magnetic shields 133 may have a flat shape in the XY plane direction. When the third magnetic shields 133 have a flat shape in the XY plane direction, the length of the third magnetic shields 133 in the Z direction is shorter than the length in the XY plane direction. As a result, the Z direction is the hard axis of shape magnetic anisotropy, and therefore the magnetization of the third magnetic shields 133 in the Z direction is less likely to be saturated. Therefore, the magnetic field strength of the first magnetic field component H1 applied to the magnetic field detector 120 tends to be effectively reduced to a stronger magnetic field.

In the Z direction, a position h1 of the third magnetic shield 133 may overlap a position h2 of the magnetic field converter 110, as shown in FIG. 3A, or may not overlap, as shown in FIG. 3E. Between these options, it is preferable that the position h1 of the third magnetic shield 133 in the Z direction overlaps the position h2 of the magnetic field converter 110 in the Z direction. As a result, the magnetic field component from the third magnetic shield 133, oriented in the XY plane direction, is less likely to be applied to the magnetic field converter 110. Therefore, the detection accuracy of the magnetic field detector 120 tends to be further improved. Note that the position h1 of the third magnetic shield 133 in the Z direction indicates a portion of the third magnetic shield 133 sandwiched between a surface 133a thereof on the first magnetic shield 131 side and a surface 133b thereof on the second magnetic shield 132 side. The position h2 of the magnetic field converter 110 in the Z direction indicates a portion of the magnetic field converter 110 sandwiched between a surface 110a thereof on the first magnetic shield 131 side and a surface 110b thereof on the second magnetic shield 132 side. The overlap of the position h1 and the position h2 means that at least one of the surfaces 133a and 133b is located between the surfaces 110a and 110b.

In the Z direction, the position h1 of the third magnetic shield 133 may overlap a position h3 of the magnetic field detector 120, as shown in FIG. 3A, or may not overlap, as shown in FIG. 3D. Between these options, it is preferable that the position h1 of the third magnetic shield 133 in the Z direction overlaps the position h3 of the magnetic field detector 120 in the Z direction as viewed in a direction orthogonal to the Z direction. In particular, as shown in FIG. 3A, it is preferable that a central position h1′ of the third magnetic shield 133 in the Z direction overlaps the position h3 of the magnetic field detector 120 in the Z direction as viewed in a direction orthogonal to the Z direction. With this configuration, when the Z magnetic field is applied, the magnetic field component converted by the third magnetic shield 133 into a component in the XY plane direction is less likely to be applied to the magnetic field detector 120. Therefore, the detection accuracy of the magnetic field detector 120 tends to be further improved. Note that the position h3 of the magnetic field detector 120 in the Z direction indicates a portion of the magnetic field detector 120 sandwiched between a surface 120a thereof on the first magnetic shield 131 side and a surface 120b thereof on the second magnetic shield 132 side. The overlap of the position h1′ and the position h3 means that a surface 133c at the central position h1′ is located between the surfaces 120a and 120b.

The third magnetic shields 133 may be located at the edges of the first magnetic shield 131 and the second magnetic shield 132, as shown in FIGS. 3A to 3F, or located deeper than the edges of the first magnetic shield 131 and the second magnetic shield 132, such as in the center, as shown in FIG. 3G.

As shown in FIG. 4A, the third magnetic shields 133 may be disposed so as to surround the entire edges of the first magnetic shield 131 and the second magnetic shield 132. In other words, the third magnetic shields 133 may be disposed so as to surround the magnetic field detector 120. In addition, as shown in FIG. 4B, the third magnetic shields 133 may be disposed so as to surround the edges of portions of the first magnetic shield 131 and the second magnetic shield 132. In other words, the third magnetic shields 133 may be disposed so as to surround a portion of the magnetic field detector 120.

As shown in FIG. 4C, the third magnetic shields 133 need not be necessarily formed at the edges of the first magnetic shield 131 and the second magnetic shield 132, and may be located deeper than the edges, such as in the center.

As shown in FIG. 4D, the third magnetic shields 133 need not be entirely disposed between the first magnetic shield 131 and the second magnetic shield 132 as long as the effect of the magnetic sensor 100 according to one example embodiment can be achieved. In FIG. 4D, the third magnetic shields 133 are separated from the first magnetic shield 131 and the second magnetic shield 132 in the X direction, but the third magnetic shields 133 may be in contact with the first magnetic shield 131 and the second magnetic shield 132.

When the magnetic sensor 100 includes a plurality of magnetic field detector 120, a third magnetic shield 133 may be provided for each magnetic field detector 120. In addition, when the first magnetic shield 131 and the second magnetic shield 132 are constituted by a plurality of magnetic shields arranged side by side in the XY plane direction, the third magnetic shields 133 may be provided for each of the plurality of combinations of a first magnetic shield 131 and a second magnetic shield 132.

Next, a method for manufacturing the magnetic sensor 100 will be briefly described. In the step of forming the magnetic detection elements 121, first, a plurality of initial magnetic detection elements that will later become the plurality of magnetic detection elements 121 are formed. Each of the plurality of initial magnetic detection elements include an initial magnetization pinned layer, which will later become a magnetization pinned layer, a free layer, a gap layer, and an antiferromagnetic layer.

Next, the direction of magnetization of the initial magnetization pinned layer is pinned to a predetermined direction using a laser beam and an external magnetic field in a predetermined direction. As a result, the initial magnetization pinned layer becomes a magnetization pinned layer 52, and the initial magnetic detection elements become the magnetic detection elements 121.

Next, the magnetic sensor chip on which the magnetic detection elements 121 are formed in this manner is fixed to a support substrate with an adhesive or the like. Thereafter, a resin layer is formed on the support substrate surface so as to cover the magnetic sensor chip. Next, through holes for vias may be formed in the resin layer at the positions of the electrodes, and the magnetic sensor 100 may be obtained by electrically connecting the support substrate and the magnetic sensor chip.

The magnetic sensor 100 according to the present disclosure may be used as part of an autofocus mechanism or an optical image stabilization mechanism of a camera module.

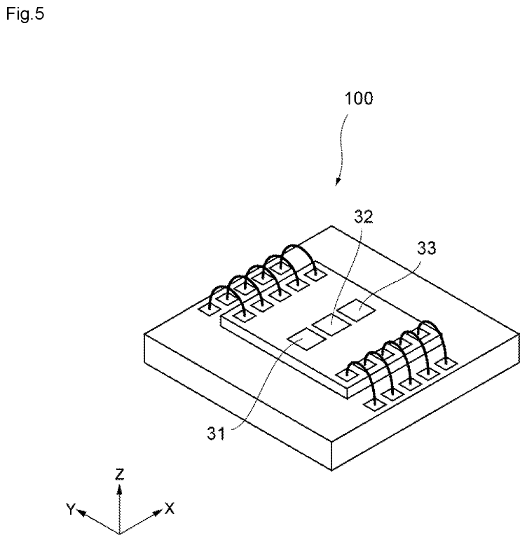

FIG. 5 is a diagram showing an example of the magnetic sensor 100 configured as a magnetic compass that generates a detected value corresponding to the angle of geomagnetism. As shown in FIG. 5, the magnetic sensor 100 includes three sensor chips 3 (first to third sensor chips 31, 32, and 33), and the first to third sensor chips 31, 32, and 33 are configured to respectively detect the components of an external magnetic field in three directions orthogonal to each other.

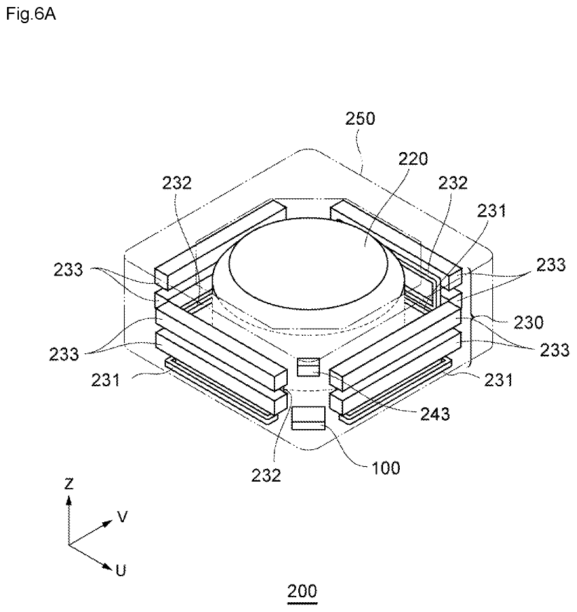

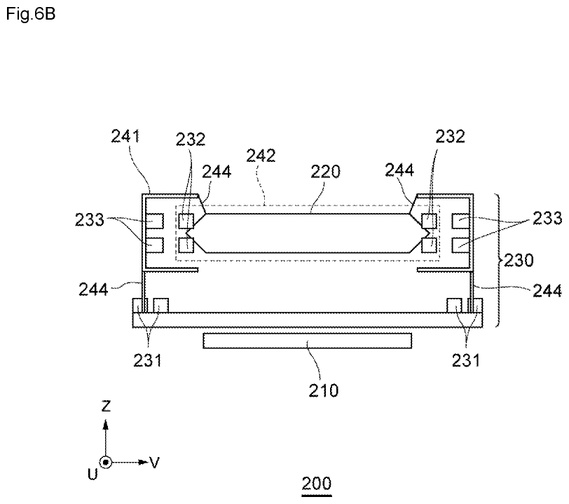

FIG. 6A is a perspective view showing an example of the magnetic sensor 100 used as part of an autofocus mechanism and an optical image stabilization mechanism of a camera module 200. FIG. 6B is a side view showing an internal structure of the camera module 200 shown in FIG. 6A. The autofocus mechanism and the optical image stabilization mechanism of the camera module 200 include a drive device 230 that moves a lens 220, and controls the drive device 230 based on position information regarding the lens 220 detected by a plurality of magnetic sensors 100.

Specifically, the autofocus mechanism detects a state in which the subject is in focus, using an image sensor, an autofocus sensor, or the like, and moves a lens in the Z direction relative to the image sensor. The optical image stabilization mechanism detects camera shake, using a gyro sensor or the like, and moves the lens in a U direction and/or a V direction with respect to the image sensor.

The camera module 200 shown in FIG. 6A includes: an image sensor 210, such as a CMOS; the lens 220 aligned with the image sensor 210; a first holding member 241 movable in the U direction and the V direction with respect to the image sensor 210; a second holding member 242 movable in the Z direction with respect to the first holding member 241; a plurality of wires 244 that are elastically deformable and support the first holding member 241 and the second holding member 242; the drive device 230 that moves the first holding member 241 and the second holding member 242; a housing 250 that accommodates these components, and so on.

The autofocus mechanism and the optical image stabilization mechanism of the camera module 200 include, in addition to the drive device 230 and a plurality of magnetic sensors 100: a processor that controls the drive device 230; an autofocus sensor that detects when the subject is in focus; a gyro sensor that detects camera shake, and so on. The processor, the autofocus sensor, the gyro sensor, and so on, which are not shown, are arranged outside the housing.

The lens 220 is fixed inside the second holding member 242, which is formed in a cylindrical shape. The second holding member 242 is housed together with the lens 220 in the first holding member 241, which is formed in a box shape. At least one second magnet 243 is fixed to the second holding member 242 so that at least one magnetic sensor 100 detects position information regarding the second holding member 242.

The drive device 230 includes a plurality of first coils 231, a plurality of second coils 232, a plurality of first magnets 233, and so on. The plurality of first coils 231 are fixed to the housing 250. The plurality of second coils 232 are fixed to the second holding member 242. The plurality of first magnets 233 are fixed to the first holding member 241. Each of the plurality of first coils 231 faces the first magnet 233 corresponding thereto. Each of the plurality of second coils 232 faces the first magnet 233 corresponding thereto.

In the case of the autofocus mechanism, when a current flows through any of the second coils 232 based on a command from the processor, the interaction between the magnetic field generated from the first magnets 233 and the magnetic field generated from the second coil 232 causes the second holding member 242 fixed to the second coil 232 to move in the Z direction. At least one magnetic sensor 100 generates a detection signal based on the synthesized magnetic field generated by combining the magnetic field generated from at least one second magnet 243 fixed to the second holding member 242 and the magnetic field generated from the first magnets 233 fixed to the first holding member 241, and transmits the detection signal to the processor. The processor detects position information regarding the lens 220 in the Z direction from the detection signal, and controls the drive device 230 so that the subject is in focus.

In the case of the optical image stabilization mechanism, when a current flows through any of the first coils 231 in response to a command from the processor, the interaction between the magnetic field generated from the first magnets 233 and the magnetic field generated from the first coil 231 causes the first holding member 241 fixed to the first magnets 233 to move in the U direction and/or the V direction. Each of the plurality of magnetic sensors 100 generates a detection signal based on the position of the first magnet 233 corresponding thereto, and transmits the detection signal to the processor. The processor detects position information regarding the lens 220 in the U direction and the V direction from the detection signal, and controls the drive device 230 to correct camera shake.

One example embodiment described above is intended to facilitate understanding of the present disclosure, and is not intended to be interpreted as limiting the present disclosure. Each element included in one example embodiment as well as its arrangement, material, conditions, shape, size, etc. are not limited to those illustrated and can be changed as appropriate. Furthermore, it is possible to partially replace or combine the structures shown in different embodiments.

For example, the magnetic sensor according to one example embodiment may be used to detect a change in position in the XY plane or a change in position in the Z direction from a change in the magnetic field in the Z direction. Examples of applications provided with the magnetic sensor include electronic devices such as an actuator used in a joint mechanism or the like of a robot, an open/close detection mechanism of a laptop computer, a joystick, a brushless motor, and a magnetic encoder.

According to the present disclosure, it is possible to provide a magnetic sensor, the magnetic field detection range of which is less likely to decrease even when a strong Z magnetic field is applied.

What is claimed is:

1. A magnetic sensor comprising:
a magnetic field detector that includes a magnetic detection element;
a first magnetic shield and a second magnetic shield that are disposed so as to sandwich the magnetic field detector therebetween in a first direction; and
a third magnetic shield that is disposed on a side of the magnetic field detector in a second direction that is orthogonal to the first direction.

2. A magnetic sensor comprising:
a magnetic field detector that includes a magnetic detection element;
a first magnetic shield and a second magnetic shield that are disposed so as to sandwich the magnetic field detector therebetween in a first direction; and
a third magnetic shield configured to converge a magnetic flux oriented in the first direction and reduce a magnetic flux applied to the magnetic field detector.

3. The magnetic sensor according to claim 1,
wherein part or all of the third magnetic shield is disposed between the first magnetic shield and the second magnetic shield.

4. The magnetic sensor according to claim 1,
wherein the third magnetic shield has a flat shape in the second direction orthogonal to the first direction.

5. The magnetic sensor according to claim 1,
wherein the magnetic field detector is provided as a plurality of magnetic field detectors, and
the third magnetic shield is formed for each of the plurality of magnetic field detectors.

6. The magnetic sensor according to claim 1, further comprising:
a magnetic field convertor configured to convert a magnetic field component oriented in the first direction into a magnetic field component oriented in a second direction that is orthogonal to the first direction, and apply the converted magnetic field component to the magnetic field detector.

7. The magnetic sensor according to claim 6,
wherein a position of the magnetic field convertor overlaps a position of the third magnetic shield as viewed from the second direction.

8. The magnetic sensor according to claim 1,
wherein the magnetic detection element is disposed obliquely with respect to the second direction orthogonal to the first direction.

9. The magnetic sensor according to claim 1,
wherein the magnetic field detector is provided as a plurality of magnetic field detectors, and
the plurality of magnetic field detectors are connected in a form of a bridge circuit.

10. The magnetic sensor according to claim 1,
wherein a position of the magnetic field detector overlaps a position of the third magnetic shield as viewed from the second direction.

11. The magnetic sensor according to claim 10,
wherein a position of the magnetic field detector overlaps a center position of the third magnetic shield in the first direction as viewed from the second direction.

12. The magnetic sensor according to claim 1,
wherein the third magnetic shield is in contact with one or both of the first magnetic shield and the second magnetic shield.

13. The magnetic sensor according to claim 1,
wherein the third magnetic shield is separated from one or both of the first magnetic shield and the second magnetic shield.

14. The magnetic sensor according to claim 1,
wherein the third magnetic shield surrounds the magnetic field detector in the second direction orthogonal to the first direction.

15. A camera module comprising:
an autofocus mechanism and/or an optical image stabilization mechanism including the magnetic sensor according to claim 1.
